(19) United States
(12) Patent Application Publication
(10) Pub. No.: US 2008/0081438 A1
(43) Pub. Date: Apr. 3, 2008

(54) Logical grouping of wafers in semiconductor processing

(76) Inventors: Mandar Chincholkar, Beaverton, OR (US); Michael J. Scott, Gilbert, AZ (US); Charles H. Winstead, Portland, OR (US); Rajshree Sankaran, Portland, OR (US)

Correspondence Address: LEE & HAYES, PLLC, P.O. BOX 52050, MINNEAPOLIS, MN, 55402, US

(21) Appl. No.: 11/541,230

(22) Filed: Sep. 29, 2006

(51) Int. Cl. H01L 21/00

(52) U.S. Cl. 438/464

(57) ABSTRACT

Embodiments of logical groups of wafers in semiconductor processing are presented herein.

### BACKGROUND

The manufacture of semiconductor devices may be complicated, involving numerous processing instructions that may be performed by a variety of devices. Therefore, the manufacture of even a single type of semiconductor device (e.g., a processor) may be complex. Additional complexity may be added as different types of semiconductor devices are to be manufactured. For example, the traditional manufacture of different semiconductor devices using the same semiconductor processing apparatus may involve significant readjustment of the apparatus as well as the materials (e.g., wafers) to be processed using the apparatus.

### BRIEF DESCRIPTION OF THE DRAWINGS

FIG. 1 is an illustration of an exemplary implementation of an environment to manufacture semiconductor devices that is operable to employ techniques to logically group wafers.

FIG. 2 is a flow diagram depicting a procedure in an exemplary implementation in which logical groups are formed for wafers within a physical carrier to be used during manufacture of semiconductor devices from the wafer.

FIG. 3 is a flow diagram depicting a procedure in an exemplary implementation in which a process manager provides recipes to a semiconductor processing apparatus to process logical groups of wafers.

The same reference numbers are utilized in instances in the discussion to reference like structures and components.

### DETAILED DESCRIPTION

In the following discussion, exemplary devices are described which may provide and/or utilize techniques to logically group wafers in semiconductor processing. Exemplary procedures are then described which may be employed by the exemplary devices, as well as by other devices without departing from the spirit and scope thereof.

Exemplary Devices

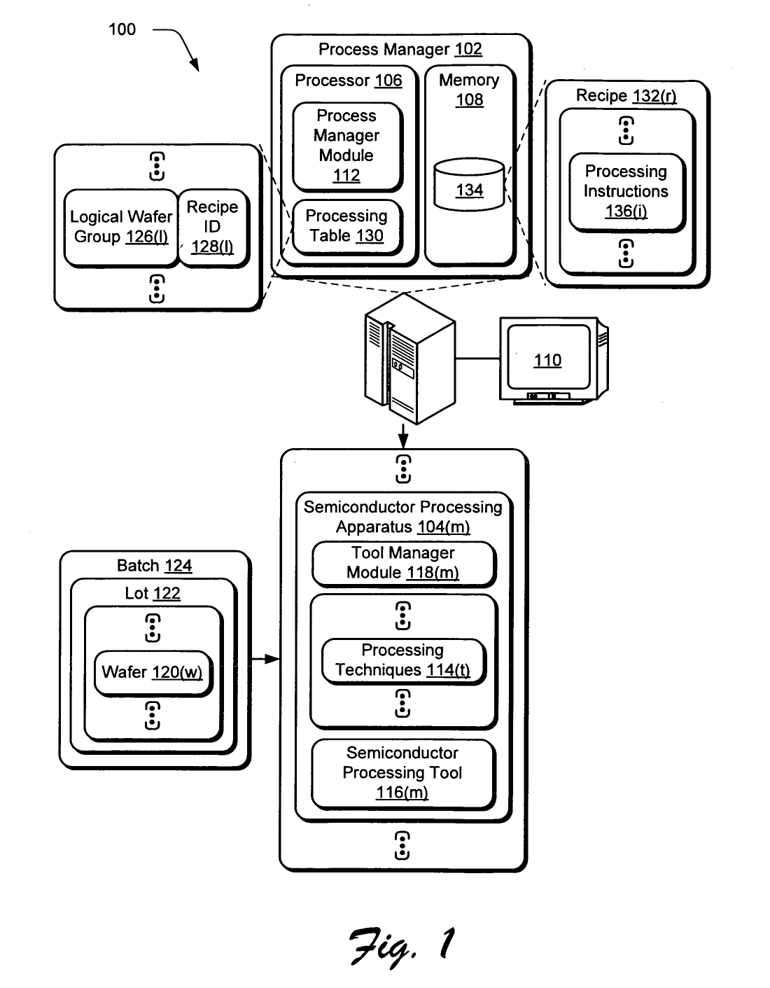

FIG. 1 illustrates an exemplary implementation of an environment 100 to manufacture semiconductor devices that is operable to employ techniques to logically group wafers. The environment 100 is representative of a semiconductor manufacturing facility which includes a process manager 102 that is communicatively coupled to one or more semiconductor processing apparatus 104(m). The process manager 102 may be configured in a variety of ways, such as computing device illustrated as a workstation in FIG. 1. In such a configuration, the process manager 102 may include a processor 106, memory 108 and an output device, which is illustrated as a display device 110 in FIG. 1 but may assume a wide variety of other configurations, such as a network interface. The display device 110 is communicatively coupled to the processor 106 via a bus, such as a host bus of a graphics memory controller hub.

The processor 106 may be configured in a variety of ways, and thus, is not limited by the materials from which it may be formed or the processing mechanisms employed therein. For example, the processor may be comprised of semiconductor(s) and/or transistors (e.g., electronic integrated circuits (ICs)), and so on. Additionally, although a single processor 106 is illustrated, the processor 106 may be representative of multiple processors that are communicatively coupled to the memory 108 through use of a bus.

The memory 108 may be representative of “main memory” of the computing device, persistent storage (e.g., a hard disk drive), removable computer-readable media (e.g., a digital video disc (DVD)), and other types of computer readable media. Likewise, although a single memory 108 is illustrated, the memory 108 may be representative of multiple memory devices, such as dynamic random access memory (DRAM) and a hard disk drive. A variety of other implementations are also contemplated.

The process manager 102 as illustrated in FIG. 1 includes a process manager module 112 that is representative of functionality to manage manufacture of semiconductor devices (e.g., computer chips, microprocessors, and so on) accomplished through use of the one or more semiconductor processing apparatus 104(m). The semiconductor processing apparatus 104(m), for instance, may employ one or more processing techniques 114(t) (where “t” can be any integer from one to “T”) that are performed by a semiconductor processing tool 116(m) to form a semiconductor device. Performance of these processing techniques 114(t) by the semiconductor processing tool 116(m) may be managed locally by a tool manager module 118(m). A wide variety of techniques and tools may be used in the manufacture of semiconductor devices, such as implant tools and techniques, thin-film tools and techniques, and so on.

The semiconductor processing tool 116(m), for instance, may employ processing techniques 114(t) to manufacture the semiconductor devices using photolithographic techniques by directing light using a mask to form a pattern from photoresist. This pattern is typically projected onto a wafer 120(w) of semiconductor material to harden the photoresist. Photoresist that is not hardened may then be washed away from the wafer 120(w) by the semiconductor processing apparatus 104(m), and more particularly the semiconductor processing tool 116(m) to leave features that form the components of the semiconductor device, such as logic gates and so on. In the following discussion, wafer 120(w) may represent a single wafer or a plurality of wafers and therefore may be referenced differently depending on the usage, e.g., wafer 120(w), the plurality of wafers 120(w), and so on.

During the manufacturing process of the semiconductor devices from the wafers 120(w), the wafers are typically arranged in physical sets called a lot 122. One lot 122 maps to one physical carrier that is used to process the wafers 120(w) by the semiconductor processing apparatus 104(m) and transport the wafers 120(w) between the semiconductor processing apparatus 104(m). One such physical carrier is referred to as a front opening unified POD (FOUP), but a wide variety of other physical carriers are also contemplated. Lots 122 may be further arranged into a batch 124. Thus, a batch 124 may have a plurality of lots 122, each of which typically includes a plurality of wafers 120(w), such as twenty-five wafers that are transported via a FOUP.

Traditional strategies that were used to process the wafers 102(w) by the semiconductor processing apparatus 104(m), however, were defined at the physical carrier level. Therefore, each wafer within a physical carrier was processed by the semiconductor device 104(m) using matching processing techniques 114(t). While this may be suitable for large scale manufacture, this increased the difficulty to selectively process wafers 120(w) arranged together in a single lot 122.

The lot 122, for instance, may include wafers 120(w) that are to be processed using different processing techniques 118(t). To process these wafers 120(w) using traditional strategies, however, the wafers 120(w) were physically separated from the physical carrier into a plurality of physical carriers according to the processing techniques that were to be performed. For instance, a first one of wafers 120(w) may be designated for processing using a first set of processing techniques and therefore be physically separated into a physical carrier apart from a second one of wafers 120(w) for processing using different processing techniques. Therefore, in this example the first wafer 120(w) and the second wafer 120(w) were each given a separate physical carrier. The physical separation was performed in a variety of ways, such as through manual separation by a technician, automated separation by a machine, and so on.

Processing instructions were then manually specified to each of the new lots by a technician and processing by the semiconductor processing apparatus was then performed. After processing, the wafers 120(w) were generally recombined back into a single physical carrier for transport and/or further processing. Thus, this traditional strategy added significant overhead in terms of time and effort, especially as the selection of different processing instructions for a lot 122 increased which caused a corresponding increase in the number of physical separations that were performed, the number of different physical carriers consumed during the manufacturing process, the vagaries of an added step and so on. Thus, the physical separation was a non-value added effort that increased cycle time.

The process manager 102, however, is configured to support selective processing of wafers 120(w) within a lot 122. Thus, the process manager 102 does not encounter the overhead resulting from physical separation of the wafers 120(w) into different lots 122 for processing by the semiconductor processing apparatus 104(m). The selective processing may be performed in a variety of ways.

The process manager module 112, for example, may support functionality to define logical wafer groups 126(l) (where “l” can be any integer from one to “L) that are not dependent on correspondence to a physical carrier. For example, each logical wafer group 126(l) may be associated with a common recipe identifier, illustrated as recipe ID 128(l) in FIG. 1. Therefore, a plurality of logical wafer groups 126(l) may be defined “within” a lot 122 to support select processing of the wafers 120(w). Thus, different processing techniques may be performed on the wafers 120(w) within the lot 122 without physically separating the wafers into different physical carriers, i.e., forming new lots. Additionally, the logical wafer groups 126(l) may encompass wafers in multiple lots, and therefore reflect wafers contained in different physical carriers.

The logical wafer groups 126(i) and the corresponding recipe IDs 128(i) may then be formed into a processing table 130 which is used by the process manager 102 to process the wafers 120(w). The process manager module 122, for instance, may fetch corresponding recipes 132(r) (where “r” can be any integer from one to “R”) from storage 134 when a corresponding logical group of wafers is identified. Each of the recipes 132(r) includes processing instructions 136(i) to configure the semiconductor processing apparatus 104(m) to perform one or more of the processing techniques 114(t) using the semiconductor processing tool 116(m). Additionally, these recipes 132(r) may be provided by the process manager 102 to the semiconductor processing apparatus 104(m) during manufacture as desired, thereby further automating the manufacturing process and causing a resultant increase in efficiency and decrease in likelihood of error. Further discussion of logical groups of wafers to manufacture semiconductor devices may be found in relation to the following figures.

It should be apparent that the environment 100 of FIG. 1 is but one example of a wide variety of environments that may be employed to manufacture semiconductor devices. For example, although the process manager 102 was illustrated in FIG. 1 apart from the semiconductor processing apparatus 104(m), the functionality of the process manager 102 may be employed by one or more (e.g., distributed) of the semiconductor processing apparatus 104(m) themselves.

Generally, any of the functions described herein can be implemented using software, firmware, hardware (e.g., fixed logic circuitry), manual processing, or a combination of these implementations. The terms “module,” “functionality,” and “logic” as used herein generally represent software, firmware, hardware or a combination thereof. In the case of a software implementation, the module, functionality, or logic represents program code that performs specified tasks when executed on a processor (e.g., CPU or CPUs such as the processor 106 of FIG. 1). The program code can be stored in one or more computer readable memory devices, e.g., memory 108 of FIG. 1. The features of the techniques to provide logical groupings described below are platform-independent, meaning that the techniques may be implemented on a variety of commercial computing platforms having a variety of processors.

Exemplary Procedures

The following discussion describes logical grouping techniques that may be implemented utilizing the previously described systems and devices. Aspects of each of the procedures may be implemented in hardware, firmware, software, or a combination thereof. The procedures are shown as a set of blocks that specify operations performed by one or more devices and are not necessarily limited to the orders shown for performing the operations by the respective blocks. In portions of the following discussion, reference will be made to the environment 100 of FIG. 1.

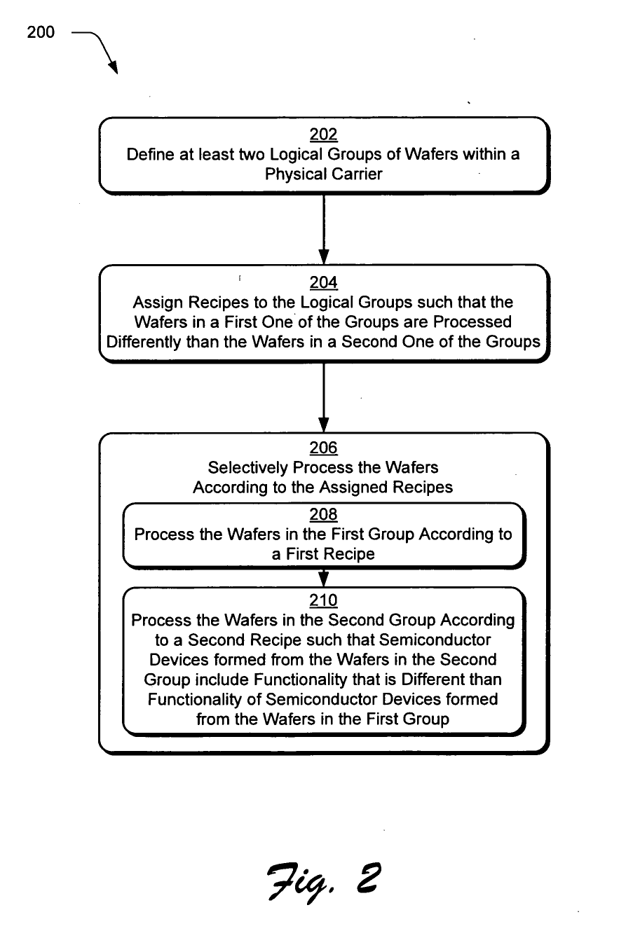

FIG. 2 depicts a procedure 200 in an exemplary implementation in which logical groups are formed for wafers within a physical carrier to be used during manufacture of semiconductor devices from the wafer. At least two logical groups are defined for wafers that are to be included in a physical carrier (block 202). Recipes are also assigned to the logical groups such that wafers in a first one of the groups are processed differently than wafers in a second one of the logical groups (block 204). The defining and the assigning may be performed in a variety of ways.

A technician, for instance, may interact with a user interface output by the process manager 102 through execution of the process manager module 112 and specify that a first number of wafers are to be processed using a first recipe and a second number of wafers are to be processing using a second recipe. The process manager module 112, upon receipt of these inputs, may then form logical wafer groups 126(l), each having an associated recipe ID 128(l). Further, the first and second number of wafers is less than a total number of wafers that may be transported using a physical carrier and these logical groups may be processed using the physical carrier.

Wafers are then selectively processed according to the recipes (block 206). The wafers in the first logical group, for instance, may be processed according to the first recipe (block 208). The wafers in the second logical group, on the other hand, are processed according to a second recipe such that the semiconductor devices formed from the wafers in the second group include functionality that is different than function of semiconductor devices formed from the first group (block 210). The semiconductor devices in the first group, for instance may include features, an arrangement of features and/or material that are different and therefore provide different functionality. Further, the processing performed on the logical groups may be implemented without physically separately the wafers into sets in separate physical carriers based on the recipe employed. Additional discussion of the definition and processing of logical groups may be found in relation to the following figure.

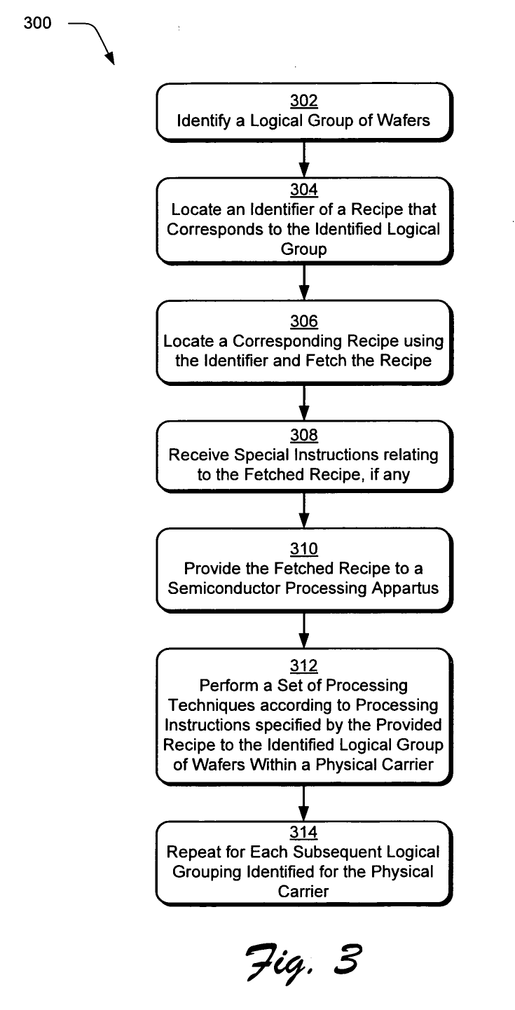

FIG. 3 depicts a procedure 300 in an exemplary implementation in which a process manager provides recipes to a semiconductor processing apparatus to process logical groups of wafers. A logical group of wafers is identified (block 302). The process manager, for example, may receive an input from the semiconductor processing apparatus that identifies a particular physical carrier, a technician may provide an input identifying the particular physical carrier, and so on. Logical groups that are to be processed from that physical carrier may then be identified by lookup to the processing table 132. Through lookup to the processing table, the processing manager may also locate an identifier of a recipe that corresponds to the identified logical group (block 304). A variety of other examples are also contemplated.

The processing manager may then use the identifier (e.g., the recipe ID 128(l)) to locate a corresponding recipe 132(r), and fetch it (block 306). In an implementation, the recipe may include special instructions that use inputs received from a technician, such as to modify one or more of the instructions, provide additional instructions, and so on. In such an implementation, the special instructions may then be received (block 308) as input by the technician.

The fetched recipe (and the additional instructions, if any) may then be provided to the semiconductor processing apparatus (block 310). The provision of the recipe may be done in a variety of ways, such as through forming a communication that includes a batch of recipes, providing the recipe one at a time, providing processing instructions in groups or in combinations from the recipe, and so on. In an implementation, the fetched recipe may also be translated to be compatible with the semiconductor processing apparatus. The semiconductor processing apparatus may then perform a set of processing techniques according to processing instructions specified by the provided recipe to the identified logical group of wafers within a physical carrier (block 312). This portion of the procedure (e.g., blocks 304-312) may then be repeated for each subsequent logical grouping identified for the physical carrier (block 314). Thus, the wafers in the logical groups contained within the physical carrier may be processed without physically separating the wafers into separate lots.

### CONCLUSION

Although the invention has been described in language specific to structural features and/or methodological acts, it is to be understood that the invention defined in the appended claims is not necessarily limited to the specific features or acts described. Rather, the specific features and acts are disclosed as exemplary forms of implementing the claimed invention.

What is claimed is:

1. A method comprising:
defining first and second logical groups of wafers within a lot, the lot corresponding to a physical carrier usable to transport the wafers to manufacture semiconductor devices; and
assigning recipes to first and second logical groups of wafers, wherein the recipes are assigned such that at least one said wafer in the first group is processed differently than another said wafer in the second group.

2. A method as described in claim 1, wherein:
each said recipe details one or more processing instructions to be performed by a semiconductor processing apparatus to form the semiconductor devices from the wafers; and
at least one said processing instruction in the recipe assigned to the first logical group is not included in the recipe assigned to the second logical group.

3. A method as described in claim 1, further comprising processing the first and second logical groups of wafers in the lot according to the respective said recipes by a semiconductor processing apparatus without physically separating the first and second logical groups into separate physical carriers.

4. A method as described in claim 1, wherein the physical carrier is a front opening unified POD (FOUP).

5. A method as described in claim 1, further comprising:
identifying the first and second logical groups of wafers to be transported using the physical carrier;
fetching corresponding said recipes for the first and the second logical groups; and
providing the corresponding said recipes to a semiconductor processing apparatus to perform processing techniques specified by the corresponding said recipes to the first and the second logical groups of wafers.

6. A method as described in claim 5, wherein the identifying, fetching and providing are performed automatically and without user intervention.

7. A method as described in claim 1, wherein the defining and the assigning are performed in response to inputs received from a user via a user interface.

8. A method as described in claim 1, further comprising:
defining a third logical group that includes at least one wafer within the lot and another wafer within another lot that corresponds to another physical carrier; and
assigning a third recipe to the third logical group.

9. A method as described in claim 1, wherein at least one recipe is configured to accept an input from a user regarding performance of a processing instruction.

10. One or more computer-readable media comprising computer executable instructions that, when executed, direct a computer to:
identify a plurality of logical groups of wafers to be transported using a physical carrier; and
fetch a recipe corresponding to each of the logical groups, wherein each said recipe includes one or more processing instructions to process the wafer to form a semiconductor device.

11. One or more computer-readable media as described in claim 10, wherein the computer executable instructions that further direct the computer to provide the fetched recipes to a semiconductor processing apparatus, wherein the fetched recipes cause the semiconductor processing apparatus to process the logical groups of wafers within a physical carrier using different processing techniques.

12. One or more computer-readable media as described in claim 10, wherein the computer executable instructions further direct the computer to output a user interface that is configured to receive inputs to:
define the logical groups of wafers within the lot; and
assign recipes to the logical groups.

13. One or more computer-readable media as described in claim 10, wherein at least one said logical group includes at least one wafer in the physical carrier and another wafer to be transported using another physical carrier.

14. One or more computer-readable media as described in claim 10, wherein:
each said recipe details one or more processing instructions to be performed by a semiconductor processing apparatus to form the semiconductor devices from the wafers; and
at least one said processing instruction in the recipe assigned to a first said logical group is not included in the recipe assigned to a second said logical group.

15. One or more computer-readable media as described in claim 10, wherein the physical carrier is a front opening unified POD (FOUP).

16. An apparatus comprising:
a semiconductor processing tool to perform one or more processing techniques to manufacture a semiconductor device; and
a module to cause the semiconductor processing tool to process logical groupings of wafers within a physical carrier using different processing techniques.

17. An apparatus as described in claim 16, wherein the physical carrier is a front opening unified POD (FOUP).

18. An apparatus as described in claim 16, wherein the semiconductor processing tool is configured to perform the one or more processing techniques on the wafers.

19. An apparatus as described in claim 16, wherein the module is configured to receive different recipes describing the different processing techniques.

20. An apparatus as described in claim 16, wherein the module is configured to process another logical grouping that includes at least one wafer in the physical carrier and another wafer in another physical carrier.
